(19) United States
(12) Patent Application Publication
(10) Pub. No.: US 2012/0090680 A1
(43) Pub. Date: Apr. 19, 2012

(54) SOLAR CELL MODULE AND METHOD FOR MANUFACTURING SOLAR CELL MODULE

(75) Inventors: Toshio Yagiura, Hyogo (JP); Satoru Ogasahara, Aichi (JP)

(73) Assignee: Sanyo Electric Co., Ltd., Moriguchi-shi, OSAKA (JP)

(21) Appl. No.: 13/380,307

(22) PCT Filed: Jun. 14, 2010
(86) PCT No.: PCT/JP2010/060021

§ 371 Date: Dec. 22, 2011

(30) Foreign Application Priority Data
Jun. 25, 2009 (JP) 2009-151068
Jun. 25, 2009 (JP) 2009-151258

(51) Int. Cl. H01L 31/0203; H01L 31/18; H01L 31/0224

(52) U.S. Cl. 136/256; 136/259; 438/98; 257/E31.124

(57) ABSTRACT

A solar cell module capable of reducing stress to which an extraction wiring member connected to an extraction electrode portion is subjected from a sealer is obtained. This solar cell module includes a solar cell formed on a substrate having insulating properties, an extraction electrode portion extracting electric charges generated by the solar cell, formed on the substrate, an extraction wiring member collecting electric charges, connected to the extraction electrode portion, a covering member covering at least part of the extraction wiring member, and a sealer sealing the solar cell, the extraction electrode portion, the extraction wiring member, and the covering member in a state of covering the solar cell, the extraction electrode portion, the extraction wiring member, and the covering member.

### TECHNICAL FIELD

The present invention relates to a solar cell module having a solar cell, etc. sealed with a sealer and a method for manufacturing a solar cell module.

### BACKGROUND ART

In general, a solar cell module having a solar cell, etc. sealed with a sealer is known. Such a solar cell module is disclosed in Japanese Patent Laying-Open No. 2007-35695, for example. This solar cell module includes an extraction electrode portion formed on a single substrate to extract electric charges generated by a plurality of solar cells to the outside. An extraction wiring member collecting the electric charges from the extraction electrode portion is connected onto the extraction electrode portion.

The plurality of solar cells, the extraction electrode portion, and the extraction wiring member are sealed with a sealer, and hence the extraction wiring member comes into direct contact with the sealer. In general, copper is employed as a base material of the extraction wiring member, and EVA (ethylene vinyl acetate) is employed as the sealer.

### PRIOR ART

### Patent Document

Patent Document 1: Japanese Patent Laying-Open No. 2007-35695

### SUMMARY OF THE INVENTION

### Problem to be Solved by the Invention

Here, the linear expansion coefficient (3.5×10⁻⁴) of EVA is larger than the linear expansion coefficient (1.7×10⁻⁵) of copper, and hence the extraction wiring member is subjected to stress from the sealer in response to temperature changes under an environment where the solar cell module is employed. Such stress is repeatedly applied to the extraction wiring member, whereby damage is accumulated in a connection portion between the extraction wiring member and the extraction electrode portion. Consequently, the connection portion is damaged, and there is such a problem that reduction in output of the solar cell module may be caused.

The present invention has been proposed in order to solve the aforementioned problem, and an object of the present invention is to provide a solar cell module capable of reducing stress to which an extraction wiring member connected to an extraction electrode portion is subjected from a sealer and a method for manufacturing a solar cell module.

### Means for Solving the Problem

A solar cell module according to a first aspect of the present invention includes a solar cell formed on a substrate having insulating properties, an extraction electrode portion extracting electric charges generated by the solar cell, formed on the substrate, an extraction wiring member collecting electric charges, connected to the extraction electrode portion, a covering member covering at least part of the extraction wiring member, and a sealer sealing the solar cell, the extraction electrode portion, the extraction wiring member, and the covering member in a state of covering the solar cell, the extraction electrode portion, the extraction wiring member, and the covering member.

A method for manufacturing a solar cell module according to a second aspect of the present invention performs, in the following order, steps of forming a solar cell and an extraction electrode portion extracting electric charges generated by the solar cell on a substrate having insulating properties, connecting an extraction wiring member collecting electric charges to the extraction electrode portion, forming a covering member covering at least part of the extraction wiring member, and forming a sealer sealing the solar cell, the extraction electrode portion, the extraction wiring member, and the covering member while covering the solar cell, the extraction electrode portion, the extraction wiring member, and the covering member.

A solar cell module according to a third aspect of the present invention includes a substrate, a power generating portion constituted by a solar cell including a first electrode layer formed on the substrate, a semiconductor layer formed on the first electrode layer, and a second electrode layer formed on the semiconductor layer, an extraction electrode portion including a connection portion connected to the first electrode layer of the solar cell, and an extraction wiring member formed on the extraction electrode portion to extract electricity generated by the power generating portion. The extraction electrode portion has an opening exposing the connection portion and a conductive portion bonding the connection portion and the extraction wiring member to each other through the opening, provided separately from an inner side surface of the opening.

### Effects of the Invention

According to the solar cell module of the first aspect and the method for manufacturing a solar cell module of the second aspect, a solar cell module capable of reducing stress to which an extraction wiring member connected to an extraction electrode portion is subjected from a sealer can be provided.

According to the solar cell module of the third aspect, reduction in reliability of a solar cell module can be suppressed.

### BRIEF DESCRIPTION OF THE DRAWINGS

FIG. 1 A plan view of a solar cell module according to a first embodiment of the present invention.

FIG. 2 A sectional view taken along the line 700-700 in FIG. 1.

FIG. 3 A sectional view (sectional view taken along the line 600-600 in FIG. 1) showing a step of manufacturing the solar cell module according to the first embodiment of the present invention.

FIG. 4 A sectional view (sectional view taken along the line 600-600 in FIG. 1) showing another step of manufacturing the solar cell module according to the first embodiment of the present invention.

FIG. 5 A sectional view (sectional view taken along the line 600-600 in FIG. 1) showing still another step of manufacturing the solar cell module according to the first embodiment of the present invention.

FIG. 6 A sectional view (sectional view taken along the line 600-600 in FIG. 1) showing a further step of manufacturing the solar cell module according to the first embodiment of the present invention.

FIG. 7 A sectional view (sectional view taken along the line 600-600 in FIG. 1) showing a still further step of manufacturing the solar cell module according to the first embodiment of the present invention.

FIG. 8 A sectional view taken along the line 800-800 in FIG. 1.

FIG. 9 A plan view of an integrated solar cell module according to a second embodiment of the present invention as viewed from the rear surface side (opposite to an incidence side).

FIG. 10 A sectional view taken along the line 900-900 in FIG. 9.

FIG. 11 A sectional view taken along the line 1000-1000 in FIG. 9.

FIG. 12 A sectional view (sectional view taken along the line 1000-1000 in FIG. 9) for illustrating a manufacturing process for the solar cell module according to the second embodiment shown in FIG. 9.

FIG. 13 A sectional view (sectional view taken along the line 900-900 in FIG. 9) for illustrating a manufacturing process for the solar cell module according to the second embodiment shown in FIG. 9.

FIG. 14 A plan view showing a solar cell module according to a modification of the second embodiment of the present invention.

### MODES FOR CARRYING OUT THE INVENTION

Embodiments of the present invention are now described with reference to the drawings. In the following description of the drawings, the same or similar portions are denoted by the same or similar reference numerals. However, it should be noted that the drawings are schematic and that their dimensional ratios and the like are different from actual ones. Therefore, specific dimensions and the like should be determined by referring to the description below. Naturally, there are portions where dimensional relationships and ratios between the drawings are different.

### First Embodiment

### Structure of Solar Cell Module

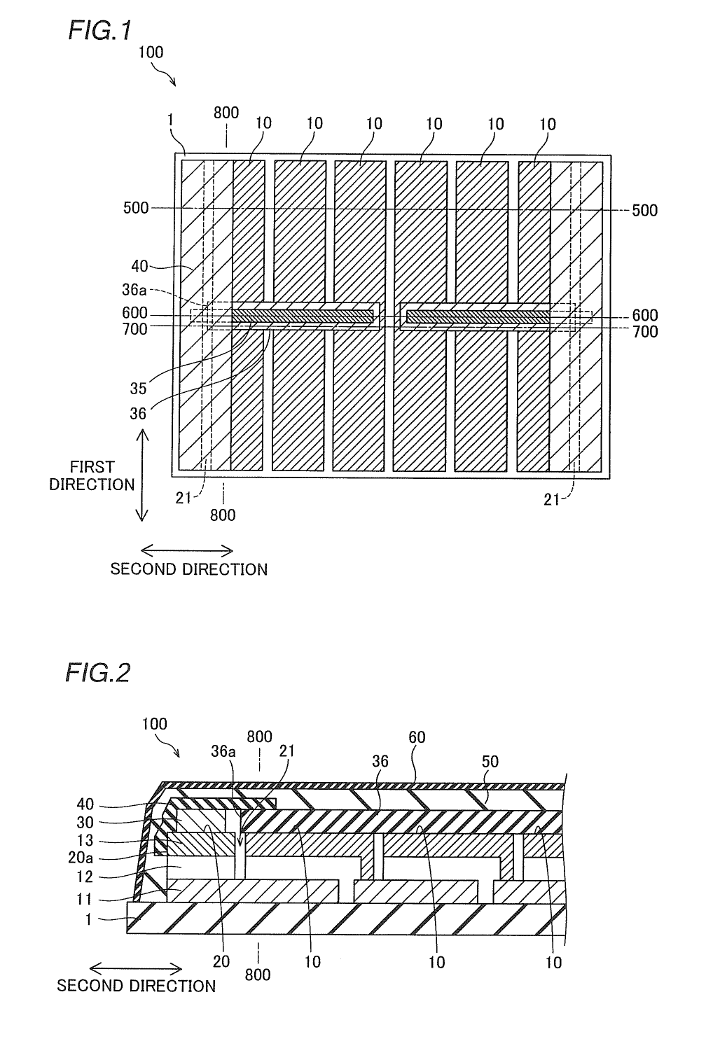

The structure of a solar cell module 100 according to a first embodiment of the present invention is described with reference to FIGS. 1, 2, and 7. FIG. 1 is a plan view of the rear surface side of the solar cell module 100. FIG. 2 is an enlarged sectional view taken along the line 700-700 in FIG. 1. FIG. 7 is an enlarged sectional view taken along the line 600-600 in FIG. 1.

As shown in FIGS. 1, 2, and 7, the solar cell module 100 includes a substrate 1, a plurality of solar cells 10, an extraction electrode portion 20, an extraction wiring member 30, an output wiring member 35, an insulating film 36, a covering member 40, a sealer 50, and a protection member 60. In FIGS. 1 and 7, the sealer 50 and the protection member 60 are omitted.

The substrate 1 is a single substrate to form the plurality of solar cells 10 and the extraction electrode portion 20. Glass, plastic, or the like having insulating properties can be employed as the substrate 1.

Each of the plurality of solar cells 10 is formed along a first direction on the substrate 1. The plurality of solar cells 10 are formed along a second direction substantially orthogonal to the first direction, and are electrically connected in series to each other.

The solar cell 10 has a first electrode layer 11, a semiconductor layer 12, and a second electrode layer 13. The first electrode layer 11, the semiconductor layer 12, and the second electrode layer 13 are successively deposited on the substrate 1, patterned by well-known laser patterning.

The first electrode layer 11 is deposited on a main surface of the substrate 1, and has conductivity and light transmission properties. As the first electrode layer 11, a metal oxide such as tin oxide (SnO₂), zinc oxide (ZnO), indium oxide (In₂O₂), or titanium oxide (TiO₂) can be employed. These metal oxides may be doped with fluorine (F), tin (Sn), aluminum (Al), iron (Fe), gallium (Ga), niobium (Nb), or the like.

The semiconductor layer 12 generates electric charges (electrons and holes) by light incident from the side of the first electrode layer 11. As the semiconductor layer 12, for example, a single body or a deposited body of an amorphous silicon semiconductor layer or a microcrystalline silicon semiconductor layer having a p-i-n junction or a p-n junction as a basic structure can be employed.

As the second electrode layer 13, for example, a single body or a deposited body of ITO, silver (Ag), or the like having conductivity can be employed. The second electrode layer 13 of one solar cell 10 is in contact with the first electrode layer 11 of a different solar cell 10 adjacent to the one solar cell 10. Thus, the one solar cell 10 and the different solar cell 10 are electrically connected in series to each other.

The extraction electrode portion 20 extracts electric charges generated by the plurality of solar cells 10. The extraction electrode portion 20 has a first electrode layer 11, a semiconductor layer 12, and a second electrode layer 13, similarly to the solar cell 10. The first electrode layer 11, the semiconductor layer 12, and the second electrode layer 13 are successively deposited on the substrate 1, patterned by well-known laser patterning. The extraction electrode portion 20 is formed to extend along the first direction on the substrate 1.

The extraction wiring member 30 extracts electric charges from the extraction electrode portion 20. In other words, the extraction wiring member 30 serves as a collection electrode collecting electric charges from the extraction electrode portion 20.

The extraction wiring member 30 is formed of a conductive base material, the outer periphery of which is solder-plated. The extraction wiring member 30 is solder-connected onto the extraction electrode portion 20 along the extraction electrode portion 20 (along the first direction). As the base material, for example, copper or the like molded into a thin-plate shape, a line shape, or a twist-line shape can be employed. The extraction wiring member 30 may be solder-connected to the extraction electrode portion 20 partially at a plurality of portions. The extraction wiring member 30 is covered with the covering member 40 described later. The extraction wiring member 30 is an example of the “first wiring member” in the present invention.

The output wiring member 35 leads electric charges collected by the extraction wiring member 30 to the outside of the solar cell module 100. The output wiring member 35 is arranged on the solar cell 10 in plan view. The output wiring member 35 has a structure similar to that of the extraction wiring member 30, and one end of the output wiring member 35 is solder-connected onto the extraction wiring member 30. The output wiring member 35 is an example of the “second wiring member” in the present invention.

The insulating film 36 is inserted between the solar cell 10 and the output wiring member 35. The output wiring member 35 is electrically isolated from the solar cell 10 by the insulating film 36. The insulating film 36 is an example of the “insulating member” in the present invention.

The covering member 40 is related to a characteristic part of the present invention, and covers the extraction wiring member 30 on the extraction electrode portion 20. The covering member 40 covers a substantially entire portion of the extraction wiring member 30 and the extraction electrode portion 20. Therefore, as shown in FIG. 2, the covering member 40 is in direct contact with the sealer 50 described later, but the extraction wiring member 30 is not in direct contact with the sealer 50. Thus, the extraction wiring member 30 is isolated from the sealer 50 by the covering member 40.

The covering member 40 according to the first embodiment has insulating properties, and is an adhesive tape obtained by forming an adhesive portion on a base material made of PET having a high melting temperature. The covering member 40 has adhesiveness on a surface closer to the extraction wiring member 30, and is bonded to the upper surface of the extraction wiring member 30.

The sealer 50 seals the plurality of solar cells 10, the extraction electrode portion 20, the extraction wiring member 30, and the covering member 40 between the substrate 1 and the protection member 60. The extraction electrode portion 20 and the extraction wiring member 30 are sealed with the sealer 50 in a state covered with the covering member 40, and hence the extraction electrode portion 20 and the sealer 50 are isolated from each other by the covering member 40. Further, the sealer 50 cushions impact applied to the solar cell module 100. As the sealer 50, a resin such as EVA, EEA, PVB, silicone, urethane, acrylic, or epoxy can be employed.

The value of the linear expansion coefficient of the covering member 40 is a value between the value of the linear expansion coefficient of the extraction wiring member 30 and the value of the linear expansion coefficient of the sealer 50. According to the first embodiment, the linear expansion coefficients of the covering member 40 (PET), the extraction wiring member 30 (copper), and the sealer 50 (EVA) are 6×10⁻⁵, 1.7×10⁻⁵, and 3.5×10⁻⁴, respectively.

The protection member 60 is arranged on the sealer 50. As the protection member 60, a single body of fluororesin (ETFE, PVDF, PCTFE, etc.), PC, PET, PEN, PVF, or resin such as acrylic, a deposited body obtained by sandwiching metallic foil between these materials, a steel plate such as SUS or galvalume, and glass in addition to a deposited body consisting of PET/Al foil/PET can be employed.

(Method for Manufacturing Solar Cell Module)

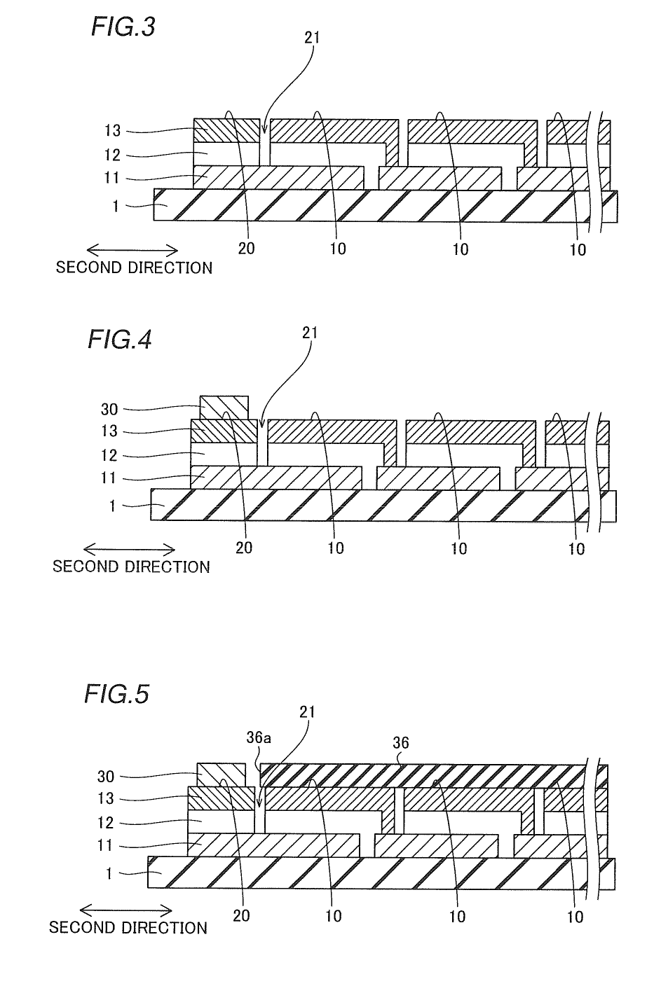

The structure of the solar cell module 100 according to the first embodiment of the present invention is hereinafter described with reference to FIGS. 1 to 8. FIGS. 3 to 7 are enlarged sectional views taken along the line 600-600 in FIG. 1 for illustrating manufacturing steps. FIG. 8 is a sectional view taken along the line 800-800 in FIG. 1.

First, the first electrode layer 11, the semiconductor layer 12, and the second electrode layer 13 are successively deposited on the substrate 1 by a film-forming method such as a CVD method or a sputtering method, as shown in FIG. 3. At this time, the first electrode layer 11, the semiconductor layer 12, and the second electrode layer 13 are successively patterned by a well-known laser patterning method to form the plurality of solar cells 10 and the extraction electrode portion 20. At this time, a groove 21 is formed along the first direction (see FIG. 1) between the extraction electrode portion 20 and the solar cell 10 adjacent to the extraction electrode portion 20.

Next, the extraction wiring member 30 is arranged on the extraction electrode portion 20 and ultrasonically soldered thereto, as shown in FIG. 4.

Subsequently, the insulating film 36 (adhesive tape) is arranged to extend over the plurality of solar cells 10 and bonded onto the plurality of solar cells 10 to be fixed, as shown in FIG. 5. An end surface 36a of the insulating film 36 in the second direction is located in the groove 21 between the extraction electrode portion 20 and the solar cell 10 adjacent to the extraction electrode portion 20.

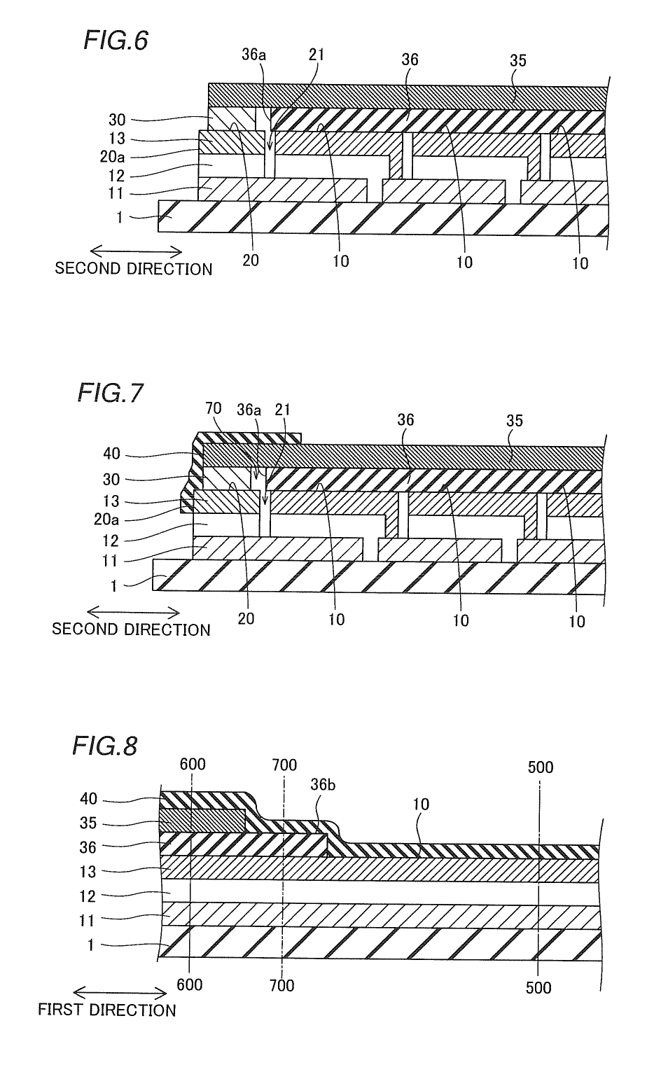

Then, the output wiring member 35 is arranged on the insulating film 36, and an end portion of the output wiring member 35 is ultrasonically soldered onto the extraction wiring member 30, as shown in FIG. 6. Thereafter, the covering member 40 (adhesive tape) is arranged on the extraction electrode portion 20 to cover the extraction wiring member 30 and bonded to be fixed, as shown in FIG. 7. At this time, an end portion of the covering member 40 is arranged to cover the whole surface of the extraction wiring member 30 and an end surface of the extraction electrode portion 20, and is bonded to a side surface 20a of the extraction electrode portion 20. A portion of the covering member 40 overlapping with the output wiring member 35 is bonded onto the output wiring member 35. Then, the covering member 40 extending to the adjacent solar cell 10 is arranged to cover a bonding surface between the extraction wiring member 30 and the extraction electrode portion 20 on the side of the solar cell 10, and is bonded onto the insulating film 36 and the second electrode layer 13 of the solar cell 10 adjacent to the extraction electrode portion 20.

Thereafter, the sealer 50 and the protection member 60 are successively deposited. At this time, an end of the output wiring member 35 is drawn through a slit formed in the sealer 50 and the protection member 60.

Next, this deposited body is thermocompression bonded in vacuum by a laminator device to complete the solar cell module 100. A frame made of Al, SUS, or iron may be attached to the solar cell module 100.

While the insulating film 36 is fixed after the extraction wiring member 30 is fixed in the method for manufacturing the solar cell module 100 according to the first embodiment, the extraction wiring member 30 may be fixed after the insulating film 36 is fixed. Further, while the output wiring member 35 is connected to the extraction wiring member 30 after the extraction wiring member 30 is connected to the extraction electrode portion 20, the extraction wiring member 30 may be connected to the extraction electrode portion 20 in a state where the output wiring member 35 is connected to the extraction wiring member 30.

(Operation and Effect)

The operation and effect of the first embodiment is described as follows:

(1) The solar cell module 100 includes the extraction electrode portion 20, the extraction wiring member 30 connected onto the extraction electrode portion 20, the covering member 40 covering the extraction wiring member 30, and the sealer 50 sealing these. The extraction electrode portion 20 and the extraction wiring member 30 are isolated from the sealer 50 by the covering member 40.

Thus, the extraction wiring member 30 is isolated from the sealer 50, and is not in direct contact with the sealer 50. Consequently, stress to which the extraction wiring member 30 is subjected from the sealer 50 in response to temperature changes under an environment where the solar cell module 100 is employed can be reduced. Therefore, a connection portion between the extraction electrode portion 20 and the extraction wiring member 30 can be inhibited from damage.

(2) The extraction electrode portion 20 and the extraction wiring member 30 are isolated from the sealer 50 by the covering member 40, and are not in direct contact with the sealer 50. Consequently, separation of the semiconductor layer 12 and the second electrode layer 13 easily caused especially when the extraction wiring member 30 is connected to the second electrode layer 13 deposited on the semiconductor layer 12 can be inhibited.

Therefore, accumulation of damage in not only the connection portion between the extraction wiring member 30 and the extraction electrode portion 20 but also the extraction electrode portion 20 itself can be inhibited. Consequently, reduction in output of the solar cell module 100 under an environment where the solar cell module 100 is employed can be further inhibited.

(3) The adhesive tape made of PET having a high melting temperature is employed as the insulating film 36, and hence the extraction wiring member 30 and the output wiring member 35 can be fixed to each other by solder after the insulating film 36 is fixed. In other words, a thermosetting resin such as EVA is not employed to fix the insulating film, and hence a poor connection between the extraction wiring member 30 and the output wiring member 35 due to EVA melted by heat generated when the extraction wiring member 30 and the output wiring member 35 are soldered to each other can be inhibited.

(4) The solar cell module 100 is prepared by connecting the output wiring member 35 to the extraction wiring member 30 after the insulating film 36 is arranged on the second electrode layer 13, not arranging the insulating film 36 between the output wiring member 35 and the second electrode layer 13 after the output wiring member 35 is fixed to the extraction wiring member 30. Consequently, physical force is not applied to a bonding surface between the output wiring member 35 and the extraction wiring member 30 when the insulating film 36 is arranged. Thus, poor connection resulting from separation of the output wiring member 35 and the extraction wiring member 30 can be prevented.

(5) The insulating film 36 is arranged on the second electrode layer 13, and thereafter the output wiring member 35 is connected to the extraction wiring member 30, and the covering member 40 covering the extraction wiring member 30 and a connection portion between the output wiring member 35 and the extraction wiring member 30 is fixed. Consequently, the covering member 40 extending to the solar cell 10 adjacent to the extraction electrode portion 20 can be bonded onto the insulating film 36 and the second electrode layer 13 of the adjacent solar cell 10.

(6) The value of the linear expansion coefficient of the covering member 40 is a value between the value of the linear expansion coefficient of the extraction wiring member 30 and the value of the linear expansion coefficient of the sealer 50, whereby stress applied to the extraction wiring member 30 can be more effectively reduced by the covering member 40.

(7) The substantially entire portion of the extraction wiring member 30 and the extraction electrode portion 20 are covered with the covering member 40, whereby the extraction wiring member 30 and the sealer 50 can be reliably isolated from each other.

(8) The covering member 40 extending to the side adjacent to the solar cell 10 is arranged on the output wiring member 35, the insulating film 36, and the solar cell 10 in a range from the line 600-600 to the line 500-500 via the line 700-700, and is bonded thereto, as shown in FIG. 8.

As shown in FIG. 8, a surface 36b to which the covering member 40 is bonded is provided on the insulating film 36, whereby level differences of bonding surfaces between the covering member 40 and the output wiring member 35, the insulating film 36, and the solar cell 10 can be inhibited from increase, and the covering member 40 can be securely bonded onto the output wiring member 35, the insulating film 36, and the solar cell 10. Consequently, gaps in the bonding surfaces between the covering member 40 and the output wiring member 35, the insulating film 36, and the solar cell 10 can be inhibited. Thus, EVA employed as the sealer 50 can be prevented from entering a space 70 surrounded by the extraction electrode portion 20, the extraction wiring member 30, and the output wiring member 35, and the extraction electrode portion 20, the extraction wiring member 30, and the output wiring member 35 are better isolated from the sealer 50 by the covering member 40, as shown in FIG. 7. Thus, a poor connection between the extraction electrode portion 20 and the extraction wiring member 30 and a poor connection between the extraction wiring member 30 and the output wiring member 35 can be prevented.

Consequently, reduction in output of the solar cell module 100 under an environment where the solar cell module 100 is employed can be inhibited.

### Second Embodiment

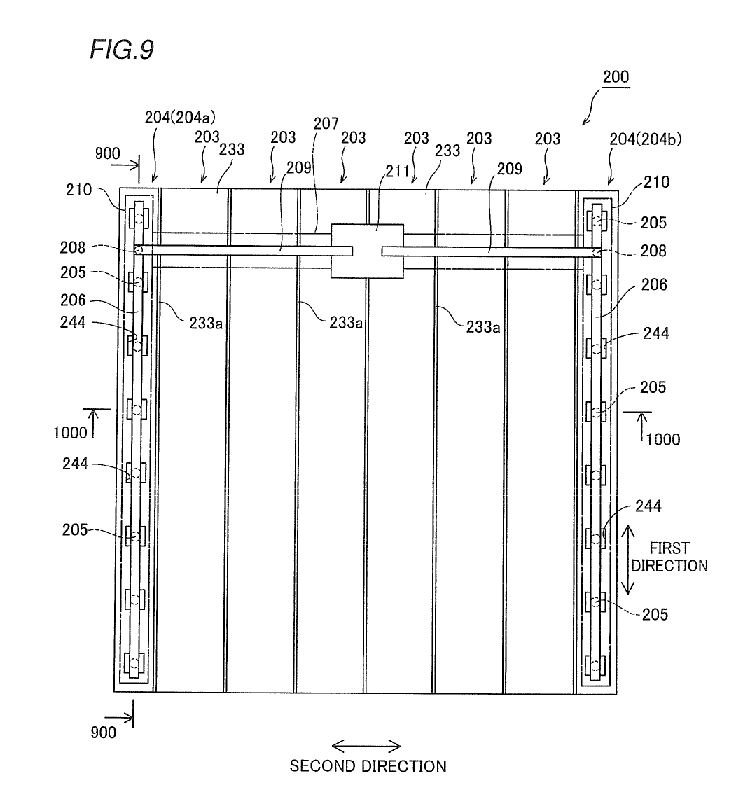

Next, the structure of an integrated solar cell module 200 according to a second embodiment of the present invention is described with reference to FIGS. 9 to 11. An example of forming openings 244 in extraction electrode portions 204 and connecting extraction wiring members 206 and first electrode layers 231 to each other is described in this second embodiment, dissimilarly to the aforementioned first embodiment in which the extraction wiring member 30 is connected to the second electrode layer 13 of the extraction electrode portion 20.

In general, adhesive strength of an interface between a first electrode layer and a semiconductor layer and an interface between the semiconductor layer and a second electrode layer is weak. Further, an extraction electrode portion is arranged on an end portion of a solar cell module, and hence moisture easily enters the extraction electrode portion from the outside, so that the first electrode layer, the semiconductor layer, and the second electrode layer of the extraction electrode portion are easily deteriorated. Consequently, separation is easily caused in the interface between the first electrode layer and the semiconductor layer of the extraction electrode portion and the interface between the semiconductor layer and the second electrode layer of the extraction electrode portion.

For example, in a solar cell module disclosed in Japanese Patent Laying-Open No. 2007-273908, solder connecting an extraction electrode portion and a first electrode layer to each other is provided to fill up an opening, and hence separating force of films is applied to the solder when separation is caused on an interface between the first electrode layer and a semiconductor layer of the extraction electrode portion and an interface between the semiconductor layer and a second electrode layer of the extraction electrode portion. Consequently, force in a direction in which the solder is separated from the first electrode layer is applied to the solder, and hence the solder is disadvantageously separated from the first electrode layer. It is difficult to extract generated electricity to the outside when the solder (conductive portion) is separated from the first electrode layer, and hence the reliability of the solar cell module is reduced.

According to the second embodiment, the aforementioned problem can be solved. The second embodiment is hereinafter described in detail.

(Structure of Solar Cell Module)

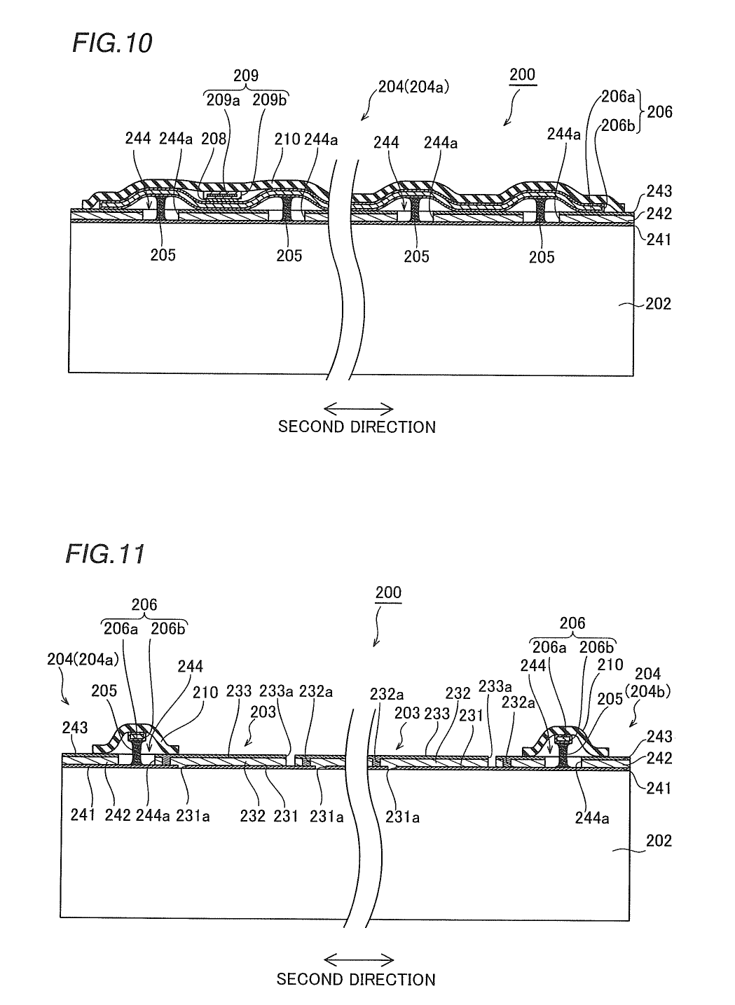

The integrated solar cell module 200 according to the second embodiment includes a substrate 202 (see FIGS. 10 and 11) provided on an incidence side, a plurality of solar cells 203 formed on a surface of the substrate 202 and connected in series to each other in a second direction, the extraction electrode portions 204 formed on the surface of the substrate 202 and connected to the solar cells 203 arranged on both end portions in the second direction, and a pair of the extraction wiring members 206 connected with the extraction electrode portions 204 by solders 205 to extract electricity generated by the solar cells 203 to the outside, as shown in FIGS. 9 to 11. The solar cell module 200 further includes an insulating film 207 provided to cover the upper surfaces of the solar cells 203, a pair of output wiring members 209 bonded to the pair of extraction wiring members 206 through solders 208, a pair of covering members 210 provided to cover the extraction wiring members 206, etc., and a terminal box 211 (see FIG. 1) connected to the output wiring members 209. A back sheet (not shown) made of glass is bonded to the rear surface of the solar cell module 200. In plan view, each of the solar cells 203 is in the form of a rectangle having long sides in a first direction orthogonal to the second direction. The extraction electrode portions 204 are formed to extend in the first direction in plan view.

The substrate 202 has an insulating surface, and is made of glass having light transmission properties. This substrate 202 has a thickness of at least about 1 mm and not more than about 5 mm.

The solar cells 203 include first electrode layers 231 formed on the surface of the substrate 202, semiconductor layers 232 formed on surfaces of the first electrode layers 231, and second electrode layers 233 formed on surfaces of the semiconductor layers 232.

The first electrode layers 231 each have a thickness of about 800 nm, and are made of a transparent conductive oxide (TCO) such as tin oxide (SnO₂), zinc oxide (ZnO), or indium tin oxide (ITO) having conductivity and light transmission properties. The first electrode layers 231 of the solar cells 203 adjacent to each other are isolated from each other by open groove portions 231a.

The semiconductor layers 232 are made of a p-i-n type amorphous silicon-based semiconductor. This semiconductor layers 232 made of a p-i-n type amorphous silicon-based semiconductor are constituted by p-type hydrogenated amorphous silicon carbide (a-SiC:H) layers each having a thickness of at least about 10 nm and not more than about 20 nm, i-type hydrogenated amorphous silicon (a-Si:H) layers each having a thickness of at least about 250 nm and not more than about 350 nm, and n-type hydrogenated amorphous silicon layers each having a thickness of at least about 20 nm and not more than about 30 nm. The semiconductor layers 232 of the solar cells 203 adjacent to each other are isolated from each other by open groove portions 232a.

The second electrode layers 233 are formed on the upper surfaces of the semiconductor layers 232. The second electrode layers 233 each have a thickness of at least about 200 nm and not more than about 400 nm, and are made of a metallic material mainly composed of silver (Ag). The second electrode layers 233 have a function of reflecting light entering the semiconductor layers 232 from the lower surface side of the substrate 202 and reaching the second electrode layers 233 thereby reintroducing the same into the semiconductor layers 232. The second electrode layers 233 of the solar cells 203 adjacent to each other are isolated by open groove portions 233a formed in regions corresponding to the open groove portions 232a. The open groove portions 233a further isolate the semiconductor layers 232 from each other, and reach the surfaces of the first electrode layers 231. TCO (ZnO or ITO, for example) having a thickness of about 100 nm may be formed between the semiconductor layers 223 and the second electrode layers 233 (between semiconductor layers 242 and second electrode layers 243 described later).

The first electrode layers 231 of first ones of the solar cells 203 adjacent to each other and the second electrode layers 233 of second ones of these solar cells 203 are connected to each other, whereby the plurality of integrated solar cells 203 connected in series to each other are formed. The plurality of solar cells 203 constitute the “power generating portion” in the present invention.

The extraction electrode portions 204 are constituted by an extraction electrode portion 204a arranged on one end, serving as a positive pole, of the solar cell module 200 in the second direction and an extraction electrode portion 204b arranged on another end, serving as a negative pole, of the solar cell module 200 in the second direction. The extraction electrode portions 204 (204a and 204b) include first electrode layers 241 formed on the surface of the substrate 202, the semiconductor layers 242 formed on surfaces of the first electrode layers 241, and the second electrode layers 243 formed on surfaces of the semiconductor layers 242. The structure, such as materials and thicknesses, of the first electrode layers 241, the semiconductor layers 242, and the second electrode layers 243 is similar to that of the first electrode layers 231, the semiconductor layers 232, and the second electrode layers 233 of the solar cells 203, respectively. The first electrode layers 241 of the extraction electrode portions 204 are formed integrally with the first electrode layers 231 of the solar cells 203 adjacent thereto. The first electrode layers 241 are examples of the “connection portion” in the present invention.

According to the second embodiment, a plurality of the hole-shaped openings 244 are formed in the extraction electrode portions 204 (extraction electrode portions 204a and 204b) to expose the first electrode layers 241 through the second electrode layers 243 and the semiconductor layers 242. The plurality of openings 244 are arranged at prescribed intervals (about 30 mm in the second embodiment) in the first direction. Each opening 244 is in the form of a square of about 4 mm on each side in plan view.

According to the second embodiment, the solders 205 bonded to the exposed first electrode layers 241 are provided in the respective openings 244. In other words, the solders 205 are plurally provided at prescribed intervals (about 30 mm in the second embodiment) in the first direction in a dotted manner. The solders 205 are in the form of circles each having a diameter of about 2 mm in plan view. In other words, the solders 205 each having the diameter of about 2 mm in plan view are arranged in the openings 244 each in the form of the square of about 4 mm on each side. Namely, the width (about 4 mm) of each of the openings 244 in the second direction is larger than the width (about 2 mm) of each of the solders 205 in the second direction, while the width (about 4 mm) of each of the openings 244 in the first direction is larger than the width (about 2 mm) of each of the solders 205 in the first direction. The solders 205 are arranged in substantially central portions of the openings 244. Thus, the outer peripheral surfaces of the circular solders 405 are separated from the overall peripheries of inner side surfaces 244a of the square openings 244. The solders 205 are made of a solder material (trade name: Cerasolzer) easily bondable to the first electrode layers 241 (metal oxide), dissimilarly to an ordinary solder material (material for the solders 208). The solders 205 are bonded to the first electrode layers 241 with an ultrasonic soldering iron. The solders 205 are examples of the “conductive portion” in the present invention.

The extraction wiring members 206 to extract electricity to the outside are provided to extend in the first direction over the plurality of openings 244, and bonded to the respective solders 205 provided in the plurality of openings 244. The extraction wiring members 206 each have a structure obtained by covering (plating) the surface of a core wire 206a made of Cu with a solder 206b, and each are flatly formed in a thickness of about 150 μm. The width (about 2 mm in the second embodiment) of each of the extraction wiring members 206 in the second direction is smaller than the width of each of the openings 244 in the second direction. According to the second embodiment, the solders 205 are arranged to bond the first electrode layers 241 and the extraction wiring members 206 to each other in the state separated from the overall peripheries of the inner side surfaces 244a of the openings 244.

The insulating film 207 is so provided as to cover portions (regions corresponding to the output wiring members 209) of the upper surface of the power generating portion in order to prevent the output wiring members 209 and the solar cells 203 (power generating portion) from an electrical short circuit. The output wiring members 209 each have a thickness of about 100 μm and a width of about 5 mm, and each have a structure obtained by covering (plating) the surface of a core wire 209a made of Cu with a solder 209b, similarly to the extraction wiring members 206. The covering members 210 are so provided as to cover the openings 244, the solder 205, the extraction wiring members 206, the output wiring members 209 (in the vicinity of the bonded portions of the extraction wiring members 206 and the output wiring members 209), etc. The covering members 210 inhibit a liquid sealer made of EVA or the like from entering the spaces between the bonded portions of the first electrode layers 241 and the extraction wiring members 206 and those of the extraction wiring members 206 and the output wiring members 209 when sealing the solar cells 203, the extraction electrode portions 204, the solders 205, the extraction wiring members 206, the insulating film 207, the solders 208, partial output wiring members 209, the covering members 210, etc. with the sealer.

### (Method for Manufacturing Solar Cell)

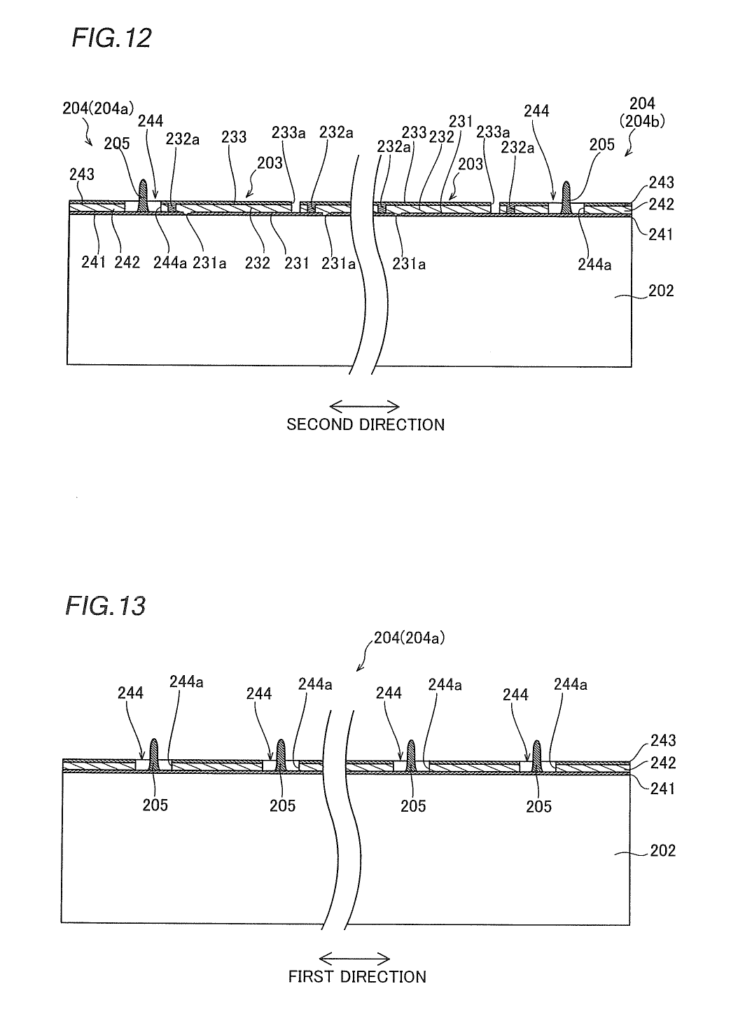

A manufacturing process for the solar cell module 200 according to the second embodiment of the present invention is now described with reference to FIGS. 9 to 13. FIGS. 10 and 13 are enlarged sectional views taken along the line 900-900 in FIG. 9. FIGS. 11 and 12 are enlarged sectional views taken along the line 1000-1000 in FIG. 9.

First, the solar cells 203 and the extraction electrode portions 204 are formed on the substrate 202.

More specifically, the first electrode layers 231 and 241, made of tin oxide, each having the thickness of about 800 nm are formed on the upper surface of the substrate 202 having the insulating surface by thermal CVD (chemical vapor deposition) method.

Then, the open groove portions 231a are formed by scanning the first electrode layers 231 with fundamental waves of a Nd:YAG laser having a wavelength of about 1064 nm, an oscillation frequency of about 20 kHz, and average power of about 14.0 W from the side of the substrate 202.

Then, the p-type hydrogenated amorphous silicon carbide layers each having the thickness of at least about 10 nm and not more than about 20 nm, the i-type hydrogenated amorphous silicon layers each having the thickness of at least about 250 nm and not more than about 350 nm, and the n-type hydrogenated amorphous silicon layers each having the thickness of at least about 20 nm and not more than about 30 nm are successively formed on the upper surfaces of the first electrode layers 231 and 241 by plasma CVD method, thereby forming the semiconductor layers 232 and 242 made of amorphous silicon-based semiconductors. Then, the open groove portions 232a are formed to be adjacent to the open groove portions 231a by scanning the semiconductor layers 232 with second harmonics of a Nd:YAG laser having a wavelength of about 532 nm, an oscillation frequency of about 12 kHz, and average power of about 230 mW from the side of the substrate 202.

Thereafter, the second electrode layers 233 and 243, made of the metallic material mainly composed of silver, each having the thickness of at least about 200 nm and not more than about 400 nm are formed on the upper surfaces of the semiconductor layers 232 and 242 by a sputtering method. At this time, the second electrode layers 233 are connected to the first electrode layers 231 of the solar cells 203 adjacent thereto through the opening groove portions 232a, in order to connect the plurality of solar cells 203 in series to each other. TCO (ZnO or ITO, for example) each having the thickness of about 100 nm may be formed between the semiconductor layers 232 and 242 and the second electrode layers 233 and 243.

Then, the open groove portions 233a isolating the second electrode layers 233 and the semiconductor layers 232 (the second electrode layers 243 and the semiconductor layers 242) from each other are formed to be adjacent to the open groove portions 232a by scanning the second electrode layers 233 with the second harmonics of the Nd:YAG laser having the wavelength of about 532 nm, the oscillation frequency of about 12 kHz, and the average power of about 230 mW from the side of the substrate 202. Thus, the solar cells 203 and the extraction electrode portions 204 are formed on the substrate 202.

Then, the plurality of openings 244 are formed by scanning the extraction electrode portions 204 with the second harmonics of the Nd:YAG laser having the wavelength of about 532 nm, the oscillation frequency of about 12 kHz, and the average power of about 230 mW from the side of the substrate 202, as shown in FIGS. 12 and 13.

Thereafter, the first electrode layers 241 exposed from the openings 244 and the solders 205 are bonded to each other with an ultrasonic soldering iron (not shown) in the respective openings 244. At this time, the solders 205 are provided to be separated from the inner side surfaces 244a of the openings 244. Thereafter, the extraction wiring members 206 are arranged to extend over the plurality of openings 244, as shown in FIGS. 10 and 11, and bonded to the solders 205 by heating the solders 205 provided in the openings 244 with a soldering iron (not shown) from above the extraction wiring members 206.

Thereafter, the insulating film 207 is bonded to cover the upper surfaces of the solar cells 203 (power generating portion) (upper surfaces of the second electrode layers 233), as shown in FIG. 9. End portions of the pair of output wiring members 209 are arranged on prescribed portions of the pair of extraction wiring members 206 through the solders 208. Then, the prescribed portions of the extraction wiring members 206 and the end portions of the output wiring members 209 are bonded to each other by the solders 208 by heating the prescribed portions of the extraction wiring members 206 with a soldering iron (not shown) from the sides of the upper surfaces of the output wiring members 209. Thereafter, the covering members 210 are bonded to cover the upper surfaces of the extraction wiring members 206 and the output wiring members 209. Finally, the solar cells 203, the extraction electrode portions 204, the solders 205, the extraction wiring members 206, the insulating film 207, the solders 208, the partial output wiring members 209, the covering members 210, etc. are sealed with the sealer made of EVA, and the back sheet (not shown) is bonded thereto.

Thus, the solar cell module 200 according to the second embodiment is formed.

(Operation and Effect)

The solar cell module 200 according to the second embodiment can attain the following effects:

(9) The solders 205 to bond the first electrode layers 241 and the extraction wiring members 206 to each other are provided separately from the inner side surfaces 244a of the openings 244 of the extraction electrode portions 204. Even if the extraction electrode portions 204 are separated on the interfaces between the first electrode layers 241 and the semiconductor layers 242 or the interfaces between the semiconductor layers 242 and the second electrode layers 243, therefore, the solders 205 can be prevented from application of the separating force. Thus, the first electrode layers 241 and the solders 205 can be inhibited from separation on the interfaces therebetween, whereby reduction in reliability of the solar cell module 200 can be suppressed.

(10) The plurality of openings 244 are provided in the extraction electrode portions 204 at the prescribed intervals along the first direction, which is the extensional direction of the extraction wiring members 206, and the first electrode layers 241 and the extraction wiring members 206 are bonded to each other by the solders 205 on a plurality of portions through the plurality of openings 244. Thus, portions (the semiconductor layers 242 and the second electrode layers 243) of the extraction electrode portions 204 other than the openings 244 are arranged in regions between the bonded portions (the openings 244) of the extraction wiring members 206 and the first electrode layers 241. Therefore, the extraction wiring members 206 can be supported from below by the portions (the semiconductor layers 242 and the second electrode layers 243) of the extraction electrode portions 204 other than the openings 244 in the regions between the bonded portions (the openings 244) of the extraction wiring members 206 and the first electrode layers 241. Even if force downwardly pressing the extraction wiring members 206 is externally applied, therefore, the force can be received from below since the extraction wiring members 206 are supported from below in the regions other than the bonded portions. Thus, the force can be inhibited from concentrated application to the bonded portions. Therefore, force applied to the extraction wiring members 206 and the solders 205 in the bonded portions can be reduced, whereby the first electrode layers 241 and the solders 205 can be inhibited from separation on the interfaces therebetween. Consequently, reduction in reliability of the solar cell module 200 can be suppressed.

(11) The openings 244 are provided in the extraction electrode portions 204, and the first electrode layers 241 and the extraction wiring members 206 are bonded to each other by the solders 205 through the openings 244, whereby the exposed areas of the first electrode layers 241 can be minimized. Thus, the time required for a process for forming the openings 244 in the extraction electrode portions 204 with a laser when the first electrode layers 241 are exposed can be reduced.

(12) The widths of the openings 244 of the extraction electrode portions 204 in the second direction are larger than the widths of the extraction wiring members 206 in the second direction, whereby the overall width of each of the extraction wiring members 206 in the second direction can be arranged in an open region of each of the openings 244. Even if film separation is caused in regions around the openings 244, therefore, separated films and edge portions of the extraction wiring members 206 on both sides (portions in the vicinity of both end portions of the extraction wiring members 206 in the second direction) can be inhibited from contact with each other. Consequently, the extraction wiring members 206 can be inhibited from application of separating force of the films.

(13) The widths of the openings 244 in the second direction are larger than the widths of the solders 205 in the second direction while the widths of the openings 244 in the first direction are larger than the widths of the solders 205 in the first direction, whereby the solders 205 can be easily provided to be separated from the inner side surfaces 244a of the openings 244.

(14) The extraction wiring members 206 are separated from the sealer by the covering members 210 not to come into direct contact with the sealer 50 in the second embodiment, similarly to the aforementioned first embodiment. Consequently, stress to which the extraction wiring members 206 are subjected from the sealer in response to temperature changes under an environment where the solar cell module 200 is employed can be reduced. Therefore, connection portions between the extraction electrode portions 204 and the extraction wiring members 206 can be inhibited from damage. The second embodiment can attain the effects as in (1) to (8) described in the aforementioned first embodiment in addition to the aforementioned effects.

### Other Embodiments

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are included.

For example, while the semiconductor layers are mainly composed of the silicon-based semiconductor materials in the aforementioned first and second embodiments, materials for the semiconductor layers are not restricted to those, but other semiconductor materials can be employed. For example, a non-silicon-based semiconductor material such as a cadmium telluride semiconductor material, or a CIS-based (copper, indium, selenium) or a CIGS-based (copper, indium, gallium, selenium) semiconductor material can be employed.

While the solar cell modules receive light on the sides of the substrates in the aforementioned first and second embodiments, the solar cell modules may receive light on the sides of the protection members. Specifically, when the solar cell modules receive light on the sides of the protection members, it is only necessary that the second electrode layers, the sealers, and the protection members have light transmission properties.

Further, the covering members may cover the extraction electrode portions and the extraction wiring members, but the extraction electrode portions and the extraction wiring members may not be in direct contact with the covering members. The extraction electrode portions and the extraction wiring members are covered with the covering members thereby being separated from the sealers by the covering members.

In addition, while the covering members cover the substantially entire portions of the extraction wiring members in the aforementioned first and second embodiments, the effects of the present invention can be achieved as long as the covering members cover at least part of the extraction wiring members. For example, when the extraction electrode portions and the extraction wiring members are connected to each other at a plurality of connection portions, it is only necessary that the covering members cover portions of the extraction wiring members other than the connection portions.

While the overall insulating films have adhesiveness in the aforementioned first and second embodiments, the insulating films may have adhesiveness on both end portions thereof or have no adhesiveness.

While the overall covering members have adhesiveness in the aforementioned first and second embodiments, the covering members may have adhesiveness on both end portions thereof or have no adhesiveness. While PET films having insulating properties, each provided in the form of a strip are employed as the covering members in the aforementioned embodiments, materials for the covering members are not restricted to insulating materials, but conductive materials such as metallic foil may be employed. Alternatively, the materials are not restricted to flexible materials, but non-flexible materials such as ceramics may be employed.

While the extraction electrode portions are formed on both ends of the plurality of solar cells in the aforementioned first and second embodiments, positions of the extraction electrode portions are not restricted to the both ends of the plurality of solar cells.

While the example of bonding the surface electrodes and the tab electrodes 6 to each other by the solders as examples of the “conductive portion” in the present invention has been shown in the aforementioned second embodiment, the present invention is not restricted to this, but the surface electrodes and the tab electrodes 6 may be bonded to each other by conductive resin as an example of the “conductive portion”.

While the example of applying the present invention to the solar cell module having a single semiconductor layer has been shown in the aforementioned second embodiment, the present invention is not restricted to this, but the present invention may be applied to a so-called tandem type solar cell module having two or more semiconductor layers (photoelectric conversion layers). In the tandem type solar cell module or the like, film stress is increased as a film thickness is increased, whereby film separation is easily caused in an extraction electrode portion. Therefore, the tandem type solar cell module or the like can further enjoy the effect of the present invention (second embodiment) “even if films are separated in the extraction electrode portions, separation of the conductive portions linked to the film separation can be inhibited, and hence reduction in reliability of the solar cell module can be suppressed”.

While the example of providing each of the openings 244 in the form of a square has been shown in the aforementioned second embodiment, the present invention is not restricted to this, but the openings 244 each may be in another form such as in the form of a circle, an ellipse, or a rectangle.

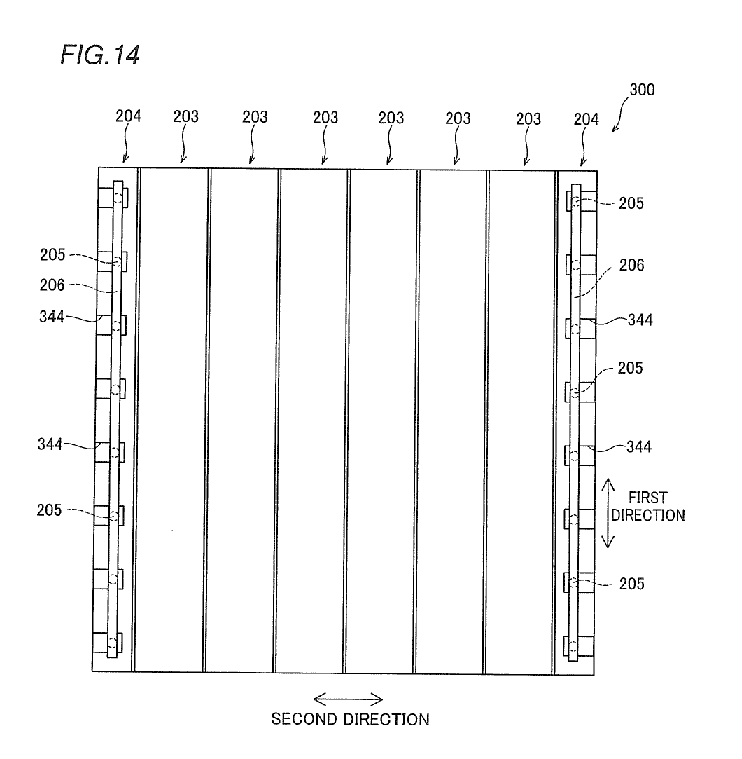

While the example of forming the openings 244 including holes has been shown in the aforementioned second embodiment, the present invention is not restricted to this, but openings 344 including notches may be formed as in a solar cell module 300 according to a modification shown in FIG. 14.

1. A solar cell module comprising:
a solar cell formed on a substrate having insulating properties;
an extraction electrode portion extracting electric charges generated by said solar cell, formed on said substrate;
an extraction wiring member collecting electric charges, connected to said extraction electrode portion;
a covering member covering at least part of said extraction wiring member; and
a sealer sealing said solar cell, said extraction electrode portion, said extraction wiring member, and said covering member in a state of covering said solar cell, said extraction electrode portion, said extraction wiring member, and said covering member.

2. The solar cell module according to claim 1, wherein
said covering member includes an adhesive tape having an adhesive surface, and
said covering member is bonded to cover a surface of said extraction wiring member.

3. The solar cell module according to claim 1, wherein
said covering member is formed to cover a substantially entire portion of said extraction wiring member.

4. The solar cell module according to claim 3, wherein
said covering member is formed to cover said substantially entire portion of said extraction wiring member and said extraction electrode portion.

5. The solar cell module according to claim 1, wherein
said extraction electrode portion includes a first electrode layer formed on said substrate, a semiconductor layer formed on said first electrode layer, and a second electrode layer formed on said semiconductor layer, and
said extraction wiring member is connected to said second electrode layer.

6. The solar cell module according to claim 1, wherein
a value of a linear expansion coefficient of said covering member is a value between a value of a linear expansion coefficient of said extraction wiring member and a value of a linear expansion coefficient of said sealer.

7. The solar cell module according to claim 6, wherein
said extraction wiring member is made of copper,
said covering member is made of polyethylene terephthalate, and
said sealer is made of ethylene vinyl acetate.

8. A method for manufacturing a solar cell module performing, in the following order, steps of:
forming a solar cell and an extraction electrode portion extracting electric charges generated by said solar cell on a substrate having insulating properties;
connecting an extraction wiring member collecting electric charges to said extraction electrode portion;
forming a covering member covering at least part of said extraction wiring member; and
forming a sealer sealing said solar cell, said extraction electrode portion, said extraction wiring member, and said covering member while covering said solar cell, said extraction electrode portion, said extraction wiring member, and said covering member.

9. The method for manufacturing a solar cell module according to claim 8, wherein
said extraction wiring member includes a first wiring member arranged on said extraction electrode portion and a second wiring member arranged on said solar cell,
the step of connecting said extraction wiring member to said extraction electrode portion includes a step of connecting said second wiring member to said extraction electrode portion through said first wiring member,
the method for manufacturing a solar cell module comprising a step of arranging an insulating member on said solar cell in advance of the step of connecting said second wiring member to said extraction electrode portion through said first wiring member.

10. The method for manufacturing a solar cell module according to claim 9, wherein
the step of connecting said second wiring member to said extraction electrode portion through said first wiring member includes a step of connecting said first wiring member to said extraction electrode portion and a step of connecting said second wiring member to said first wiring member connected onto said extraction electrode portion, and
the step of arranging an insulating member on said solar cell is performed in advance of the step of connecting said second wiring member to said first wiring member connected onto said extraction electrode portion.

11. The method for manufacturing a solar cell module according to claim 8, wherein
the step of forming said covering member includes a step of bonding said covering member by an adhesive tape having an adhesive surface to cover a surface of said extraction wiring member.

12. The method for manufacturing a solar cell module according to claim 8, wherein
the step of forming said covering member includes a step of forming said covering member to cover a substantially entire portion of said extraction wiring member.

13. The method for manufacturing a solar cell module according to claim 12, wherein
the step of forming said covering member includes a step of forming said covering member to cover said substantially entire portion of said extraction wiring member and said extraction electrode portion.

14. The method for manufacturing a solar cell module according to claim 8, wherein
the step of forming said extraction electrode portion includes a step of forming a first electrode layer formed on said substrate, a step of forming a semiconductor layer formed on said first electrode layer, and a step of forming a second electrode layer formed on said semiconductor layer, and
the step of connecting said extraction wiring member to said extraction electrode portion includes a step of connecting said extraction wiring member to said second electrode layer.

15. The method for manufacturing a solar cell module according to claim 8, wherein
a value of a linear expansion coefficient of said covering member is a value between a value of a linear expansion coefficient of said extraction wiring member and a value of a linear expansion coefficient of said sealer.

16. The method for manufacturing a solar cell module according to claim 15, wherein
said extraction wiring member is made of copper,
said covering member is made of polyethylene terephthalate, and
said sealer is made of ethylene vinyl acetate.

17. A solar cell module comprising:
a substrate;
a power generating portion constituted by a solar cell including a first electrode layer formed on said substrate, a semiconductor layer formed on said first electrode layer, and a second electrode layer formed on said semiconductor layer;
an extraction electrode portion including a connection portion connected to said first electrode layer of said solar cell; and
an extraction wiring member formed on said extraction electrode portion to extract electricity generated by said power generating portion, wherein
said extraction electrode portion has an opening exposing said connection portion and a conductive portion bonding said connection portion and said extraction wiring member to each other through said opening, provided separately from an inner side surface of said opening.

18. The solar cell module according to claim 17, wherein
said extraction electrode portion is provided with a plurality of said openings and a plurality of said conductive portions at prescribed intervals along a first direction, which is an extensional direction of said extraction wiring member, and
said extraction wiring member is bonded to said connection portion by a plurality of said conductive portions through a plurality of said openings.

19. The solar cell module according to claim 17, wherein
a width of said opening in a second direction orthogonal to said first direction is larger than a width of said extraction wiring member in said second direction.

20. The solar cell module according to claim 17, wherein
said extraction electrode portion includes said connection portion formed integrally with said first electrode layer of said solar cell located on an end portion of said power generating portion, a layer identical to said semiconductor layer, and a layer identical to said second electrode layer, and
said opening is formed by passing through said layer identical to said semiconductor layer and said layer identical to said second electrode layer at prescribed portions to expose said connection portion.
